(19) United States
(12) Patent Application Publication
(10) Pub. No.: US 2018/0072857 A1
(43) Pub. Date: Mar. 15, 2018

(54) Gas Barrier Coating For Semiconductor Nanoparticles

(71) Applicant: Nanoco Technologies Ltd., Manchester (GB)

(72) Inventors: Nigel Pickett, Manchester (GB); Cong-Duan Vo, Manchester (GB)

(21) Appl. No.: 15/699,182

(22) Filed: Sep. 8, 2017

Related U.S. Application Data
(60) Provisional application No. 62/393,325, filed on Sep. 12, 2016.

(51) Int. Cl. C08J 5/18; C08K 9/10; B32B 37/24; C09K 11/02; F21K 9/64

(52) U.S. Cl. CPC C08J 5/18; C08K 9/10; H01L 33/50; C09K 11/025; F21K 9/64; B32B 37/24

(57) ABSTRACT

A thin silazane coating cured with short-wavelength UV radiation is highly transparent, exhibits good oxygen-barrier properties, and does minimal damage to quantum dots in a quantum dot-containing film.

### CROSS-REFERENCE TO RELATED APPLICATIONS

This application claims the benefit of U.S. Provisional Patent Application No. 62/393,325 filed on Sep. 12, 2016, the contents of which are hereby incorporated by reference in their entirety.

### STATEMENT REGARDING FEDERALLY SPONSORED RESEARCH OR DEVELOPMENT

Not Applicable

### BACKGROUND OF THE INVENTION

### 1. Field of the Invention

The present invention generally relates to semiconductor nanoparticles—also known as “quantum dots” (QDs). More particularly, it relates to coatings applied to QD-containing films, beads, and the like to protect the QDs from deleterious environmental factors, especially oxygen and moisture.

### 2. Description of the Related Art Including Information Disclosed Under 37 CFR 1.97 and 1.98

Quantum dots benefit from gas barrier encapsulation when used in display and lighting applications. In one particular preferred method, QDs are first dispersed in highly compatible materials such as organic amphiphilic macromolecules or polymers to form an inner phase that prevents agglomeration of the quantum dots thereby maintaining the optical performance of the quantum dots. The inner phase is subsequently encapsulated in an outer phase resin having lower oxygen permeability.

U.S. Pat. No. 9,708,532 discloses multi-phase polymer films of quantum dots. The QDs are absorbed in a host matrix, which is dispersed within an outer polymer phase. The host matrix is hydrophobic and is compatible with the surface of the QDs. The host matrix may also include a scaffolding material that prevents the QDs from agglomerating. The outer polymer is typically more hydrophilic and prevents oxygen from contacting the QDs. U.S. Pat. No. 9,680,068 also discloses multi-phase polymer films containing quantum dots. The films have domains of primarily hydrophobic polymer and domains of primarily hydrophilic polymer. QDs, being generally more stable within a hydrophobic matrix, are dispersed primarily within the hydrophobic domains of the films. The hydrophilic domains tend to be effective at excluding oxygen.

Such organic two-phase resins show better oxygen barrier properties but are insufficient to stabilize the quantum dots under irradiation at high temperatures and high humidity such as may be encountered in back light units (BLUs) inasmuch as oxygen can still migrate through the encapsulant to the surface of the quantum dots which can lead to photo-oxidation and a resulting drop in quantum yield. Current practice is to sandwich the quantum dot-containing resin between two barrier films. Polymer beads embedded with QDs are more challenging to stabilize inasmuch as they require a conformal layer of a thin inorganic coating (e.g., Al₂O₃). Coating beads or the like using atomic layer deposition (ALD) processes is very time-consuming and difficult to scale up. Moreover, significantly decreased quantum yields (QYs) have been observed after ALD coating.

Silazane-based coatings are an alternative to both barrier films and an inorganic coating on beads. A silazane is a hydride of silicon and nitrogen having a straight or branched chain of silicon and nitrogen atoms joined by covalent bonds. Organic derivatives of such compounds are also called silazanes. They are analogous to siloxanes, with —NH— replacing —O—. Their individual names are dependent on the number of silicon atoms in the chemical structure. For example, hexamethyldisilazane (or bis(trimethylsilyl)amine; [(CH₃)₃Si]₂NH) contains two silicon atoms bonded to the nitrogen atom.

Thermal curing of silazane coatings has been tested by Applicant. However, thermal curing was found to cause significant damage to the QDs. The thermally cured silazane coating was not sufficient to stabilize the quantum dots in films or beads. Accordingly, a UV-curable silazane rather than a thermally cured silazane was tested in order to minimize damage to the quantum dots.

### BRIEF SUMMARY OF THE INVENTION

It has been discovered that a thin silazane coating cured with short-wavelength UV radiation is highly transparent, exhibits good oxygen-barrier properties, and causes minimal damage to quantum dots. The process is not as time-consuming as ALD and may be used for the large-scale production of QD-containing films and polymer or inorganic beads containing quantum dots.

It has been discovered that the silazane coating works particularly well when the quantum dots are embedded in a two-phase resin system. It is contemplated that the use of a two-phase resin system may enhance the stability of the quantum dots particularly when the silazane is undergoing UV curing.

In a test, 10-cm×10-cm peelable films with an approximately 100-μm white resin layer comprising green-fluorescing CFQD® quantum dots [Nanoco Technologies Ltd., Manchester UK] laminated between 125-μm barrier films were prepared. Unmodified films were used as control samples. Test samples were prepared by peeling off one of the barrier films, coating the surface so exposed with a UV-curable silazane coating [poly(perhydrosilazane); CAS number: 90387-00-1 ENCS number: (2)-3642] on the films, and then exposing the silazane precursor to UV radiation. Optical and lifetime reliability of the silazane-coated films were then evaluated. This method can be extended to coating polymer beads containing embedded quantum dots.

Silazane-coated, QD-containing films are particularly advantageous in ultra-thin devices (e.g., mobile phones) inasmuch as a relatively thin layer of silazane is required relative to the barrier coatings of the prior art.

### BRIEF DESCRIPTION OF THE SEVERAL VIEWS OF THE DRAWING(S)

FIG. 1 is a schematic representation of the preparation of a silazane coating for quantum dot-containing films according to an embodiment of the invention.

FIG. 2 is a cross-sectional view of the QD-containing films for which test results are presented in FIG. 3.

FIG. 3 contains graphs showing the change versus time (relative to initial values) in green QD emission peak intensity, LED intensity, and external quantum efficiency (EQE) for various quantum dot-containing films.

FIG. 4A shows the general chemical structure of a substituted silazane.

FIG. 4B is the chemical structure of one particular representative polycyclic silazane.

FIG. 4C is the chemical structure of another silazane. In certain trials reported hereinbelow, R⁸, R⁹, and R¹⁹═H in the particular silazane used.

### DETAILED DESCRIPTION OF THE INVENTION

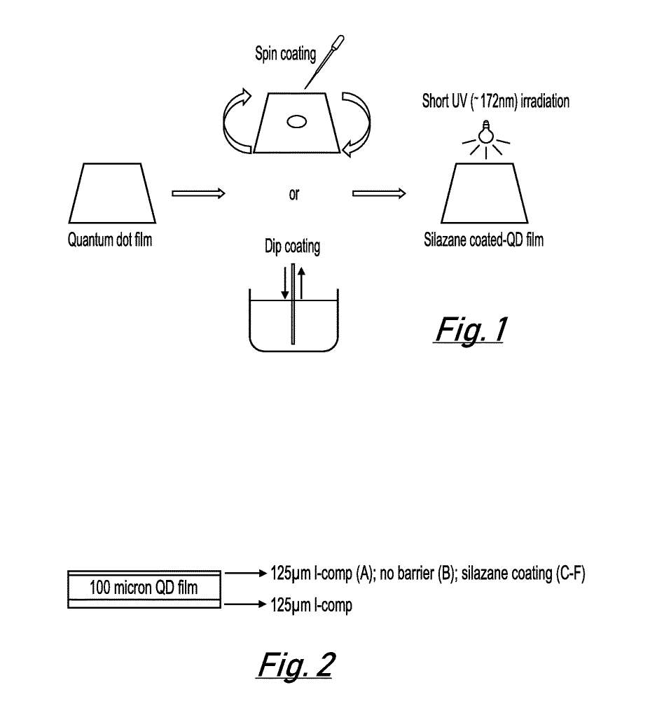

In one particular exemplary embodiment of the invention, 100-micron thick, QD films were prepared using a two-phase resin system. A resin layer containing green-emitting quantum dots having a 521-nm PLₘₐₓ, a 43-nm FWHM, and an 80% QY was laminated between two 125-micron barrier films (I-Component Co. Ltd., S. Korea). The films showed either excellent adhesion to the barrier film or one-side peelable depending on which side of the barrier film the QD-containing resin was in contact with. The bare side of the peelable QD films was then coated with silazane precursors as shown in FIG. 1. Spin coating was used for this particular study but dip coating or spraying may also be used to control the thickness of the silazane coating (see FIG. 1). Slot die coating is also feasible and may be preferable for industrial-scale production. The coated films were then baked (80° C., 3 min.) to remove solvent before being irradiated (under nitrogen) with short-wavelength UV radiation (172-nm Xenon excimer lamp; >100 mV/cm²; 2-6-mm radiation gap) at different doses. The thickness of the silazane coating may be controlled by varying the silazane concentration and the speed of rotation or dipping if spin or dip coating is used, respectively. Two-phase resin systems may provide enhanced protection for the quantum dots from damage by the UV curing radiation.

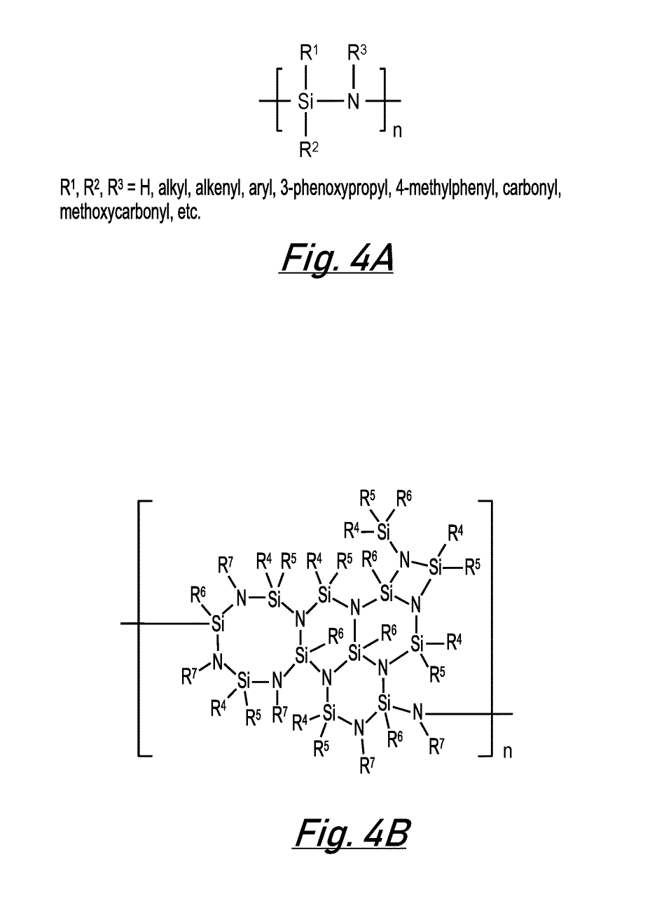

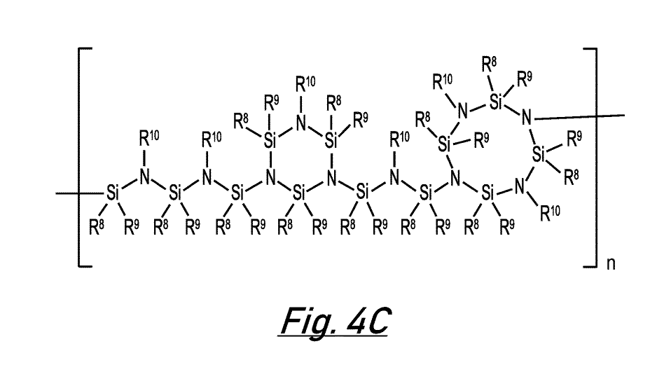

Referring now to FIG. 3, stability test results for various QD-containing films are presented in graphical format. Graph A is for QD two-phase system films encapsulated between two commercial barrier films (I-Component Co. Ltd.) as a control. Graph B is for QD films with a commercial barrier film (I-Component Co. Ltd.) on one side only. Graph C is for a QD film with a commercial barrier film (I-Component Co. Ltd.) on one side and a 200-nm silazane coating cured with high-dose [7 J/cm²] UV radiation on the other side. Graph D is for a QD film with a commercial barrier film (I-Component Co. Ltd.) film on one side and 200-nm silazane coating cured at low dose [4 J/cm²] on the other side. Graph E is for a QD film with a commercial barrier film (I-Component Co. Ltd.) on one side and a 100-nm silazane coating cured with high-dose [7 J/cm²] UV radiation on the other side. Graph F is for a QD film with a commercial barrier film (I-Component Co. Ltd.) on one side and a 100-nm silazane coating cured with low-dose [4 J/cm²] UV radiation on the other side.

Table 1 presents certain optical data of the control film (sample A, QD film encapsulated between two commercial barrier films) and for films having a commercial barrier film on one side and either no barrier or a silazane coating on the other side. The control film shows high QY of 61% and EQE of 45% while QY and EQE of the QD film having no barrier on one side (sample B) are only 40% and 32%, respectively suggesting the commercial barrier film protected the quantum dots from (photo-) oxidation. The QYs of silazane coated films, however, are slightly lower than the control indicating that the coating process had some negative impact on quantum dots. The films with thinner silazane coatings (sample E and F) show higher QY and EQE than films having thicker silazane coatings suggesting that an optimum silazane coating thickness for QD films may exist.

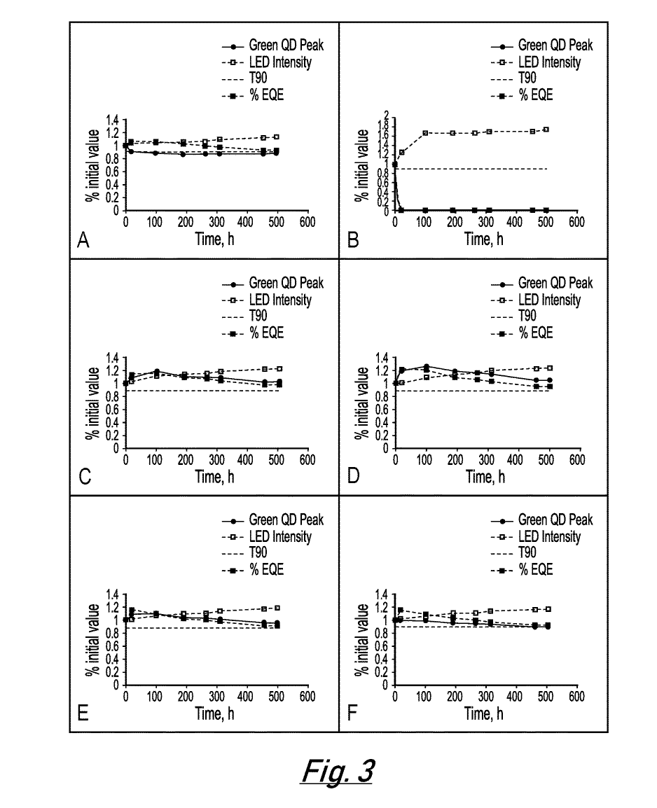

TABLE 1
Quantum yield and quantum efficiency of
the QD-containing films shown in FIG. 2.

| Sample | | QY | EQE | Abs |
|---|---|---|---|---|
| code | Barrier | (%) | (%) | (%) |
| A (control) | Commercial barrier film | 61 | 45 | 47 |
| B | No silazane coating | 40 | 32 | 50 |
| C | 200-nm silazane coating; low dose | 45 | 33 | 49 |
| | [4 J/cm²] | | | |
| D | 200-nm silazane coating; high dose | 46 | 33 | 50 |
| | [7 J/cm²] | | | |
| E | 100-nm silazane coating; low dose | 53 | 37 | 49 |
| | [4 J/cm²] | | | |
| F | 100-nm silazane coating; high dose | 52 | 37 | 50 |
| | [7 J/cm²] | | | |

Lifetimes of the above QD films on a light test were performed by illuminating these films with 450-nm blue light having an intensity of 106 mW/cm² at 60° C. and at 90% relative humidity. QD emission peak intensity was monitored versus time (FIG. 3). Without a gas barrier, the green-emitting QDs in sample B degraded completely within a few hours while the control films and silazane-coated films behaved similarly to one another—i.e. green-emitting quantum dots remained stable after 500 hours. The green-emitting quantum dots were more stable in thicker silazane-coated films than those in films with a thinner silazane coating. The stability of QD films with a silazane coating suggests that the oxygen-barrier property of a silazane coating is equal to or even better than that of the commercial barrier film. It is noted that the dosage of the curing UV radiation does not affect QY and/or EQE, and the stability of the silazane-coated films confirms the advantages of short-UV curing for the thin barrier coating (which minimizes damage to the quantum dots due to its low penetration depth).

It is also possible to coat QD-containing polymer beads or other three-dimensional objects (such as LED caps and the like) with a silazane. Quantum dot-containing beads may be coated with a silazane precursor in, for example, a fluidized bed using either an inert gas or a non-solvent for the silazane precursors before the curing process takes place.

The foregoing presents particular embodiments of a system embodying the principles of the invention. Those skilled in the art will be able to devise alternatives and variations which, even if not explicitly disclosed herein, embody those principles and are thus within the scope of the invention. Although particular embodiments of the present invention have been shown and described, they are not intended to limit what this patent covers. One skilled in the art will understand that various changes and modifications may be made without departing from the scope of the present invention as literally and equivalently covered by the following claims.

What is claimed is:

1. A fluorescent film comprising:
a quantum dot-containing layer having a first side and an opposing second side;
a silazane coating on at least one of the first side and the second side of the quantum dot-containing layer.

2. The fluorescent film recited in claim 1 further comprising a silazane coating on both the first side and the second side of the quantum dot-containing layer.

3. The fluorescent film recited in claim 1 wherein the silazane coating is on the first side of the quantum dot-containing layer and further comprising a barrier film on the second side of the quantum dot-containing layer.

4. The fluorescent film recited in claim 1 wherein the quantum dot-containing layer produces green light when illuminated by a source of blue light.

5. The fluorescent film recited in claim 1 wherein the quantum dot-containing layer comprises quantum dots embedded in a polymer resin.

6. A fluorescent bead comprising:
a quantum dot-containing body;
a silazane coating on the quantum dot-containing body.

7. A fluorescent cap for a light emitting diode (LED) comprising:
a quantum dot-containing body having a top surface, an opposing bottom surface, and at least one side surface;
a silazane coating on at least one of the top surface, the bottom surface, and the at least one side surface of the quantum dot-containing body.

8. The fluorescent cap for an LED recited in claim 7 wherein the silazane coating is on each of the top surface, the bottom surface, and the at least one side surface of the quantum dot-containing body.

9. The fluorescent cap for an LED recited in claim 7 wherein the quantum dot-containing body is configured such that the bottom surface is illuminated by the LED and the top surface emits fluorescent light produced by the quantum dots when the cap is installed on a package containing the LED.

10. The fluorescent cap for an LED recited in claim 7 wherein the quantum dot-containing body comprises quantum dots embedded in a polymer resin.

11. A method for applying a silazane coating to a thin film comprising quantum dots, the method comprising:
applying a silazane precursor to at least one side of the thin film comprising quantum dots;
curing the silazane precursor by exposing the thin film having a silazane precursor applied thereto to ultraviolet (UV) radiation.

12. The method recited in claim 11 wherein the UV radiation is short-wavelength UV radiation.

13. The method recited in claim 12 wherein the UV radiation has a wavelength of about 172 nm.

14. The method recited in claim 11 wherein the thin film having a silazane precursor applied thereto is exposed to the UV radiation at an intensity of about 7 J/cm².

15. The method recited in claim 11 wherein the silazane precursor is perhydrosilazane

16. The method recited in claim 11 further comprising heating the thin film having applied silazane precursors to a temperature and for a time sufficient to substantially remove a solvent in which the silazane precursors are dissolved.

17. The method recited in claim 16 wherein the heating to remove the solvent is performed at about 80° C. for about 3 minutes.

18. A method for applying a silazane coating to polymer beads comprising quantum dots, the method comprising:
fluidizing the polymer beads comprising quantum dots;
applying a silazane precursor to the fluidized polymer beads comprising quantum dots;
curing the silazane precursor by exposing the polymer beads having a silazane precursor applied thereto to ultraviolet (UV) radiation.

19. The method recited in claim 18 wherein fluidizing the polymer beads comprises fluidizing the polymer beads using an inert gas.

20. The method recited in claim 18 wherein fluidizing the polymer beads comprises fluidizing the polymer beads using a non-solvent for the silazane precursors.
